(19) United States
(12) Patent Application Publication
(10) Pub. No.: US 2020/0326762 A1
(43) Pub. Date: Oct. 15, 2020

(54) COVER MEMBER AND COVERED PORTABLE INFORMATION DEVICE

(71) Applicant: LENOVO (SINGAPORE) PTE. LTD., SINGAPORE (SG)

(72) Inventors: Akinori Uchino, YOKOHAMA (JP); Takuroh Kamimura, YOKOHAMA (JP); Ryota Watanabe, YOKOHAMA (JP); Atsushi Ohyama, YOKOHAMA (JP)

(73) Assignee: LENOVO (SINGAPORE) PTE. LTD., SINGAPORE (SG)

(21) Appl. No.: 16/458,184

(22) Filed: Jun. 30, 2019

(30) Foreign Application Priority Data
Apr. 11, 2019 (JP) 2019075674

(51) Int. Cl. G06F 1/20; H05K 5/03; G06F 1/16

(52) U.S. Cl. CPC G06F 1/203; H05K 5/03; G06F 2200/1634; G06F 1/1656; G06F 1/1616

(57) ABSTRACT

A cover member is capable of dispersion of heat generated in a portable information device. A cover member is to be mounted on a portable information device. The cover member includes a first cover portion, a second cover portion, a connecting portion connecting the first cover portion and the second cover portion in a foldable manner, and a heat conductive sheet disposed so as to extend from the first cover portion to the second cover portion through the connecting portion.

### FIELD OF THE INVENTION

The present invention relates to a cover member to be mounted on a portable information device, and a covered portable information device including the cover member and a portable information device.

### BACKGROUND OF THE INVENTION

In recent years, portable information devices, such as laptop personal computers, tablet personal computers, and smartphones, have rapidly become very popular. For such portable information devices, it is necessary to prevent damage and breakage while carrying the devices. In view of the above, various cover members have been provided for such portable information devices for protection or decoration purpose. The present applicant has proposed in Japanese Unexamined Patent Application Publication No. 2018-105961 cover members adapted to be used with foldable tablet PCs.

### SUMMARY OF THE INVENTION

The portable information device disclosed in Japanese Unexamined Patent Application Publication No. 2018-105961 mentioned above includes a pair of chassis connected to each other in a foldable manner. Of the chassis, one chassis carries an electronic component, such as a CPU, that generates a large amount of heat. This leads to a difference in the amount of heat generated between the right and left chassis of this portable information device. In the case of the structure disclosed in Japanese Unexamined Patent Application Publication No. 2018-105961 mentioned above, a part of the outer surface of the cover member, the part covering one chassis with large heat generation amount becomes very hot. That is, the temperature of the part is very different from the temperature of a part covering the other chassis. Accordingly, the heat generated in the chassis at higher temperature is locally transmitted to a user via the cover member covering that part. This local heat transmission may raise a concern that the user might feel uncomfortable in using the device. This problem is similarly applicable to cover members to be mounted on normal, that is, not foldable, tablet PCs or smartphones as well.

The present invention has been conceived in view of the above-mentioned problem of conventional art, and aims to provide a cover member capable of dispersion of heat generated in a portable information device and a covered portable information device including the cover member and a portable information device.

A cover member according to the first aspect of the present invention is a cover member to be mounted on a portable information device and includes a first cover portion; a second cover portion; a connecting portion connecting the first cover portion and the second cover portion in a foldable manner; and a heat conductive sheet disposed so as to extend from the first cover portion to the second cover portion through the connecting portion.

With this structure, for example, the cover member can absorb heat of the portable information device with the first cover member and disperse the heat over a large area up to the second cover member. With the above, the cover member can efficiently disperse the heat generated in the portable information device, and can thus make the temperature over the outer surface of the first cover portion and the second cover portion substantially constant. Hence, the cover member enables avoiding a situation in which heat from a portable information device makes a user feel uncomfortable.

The cover member may further include an inner cover member extending from the first cover portion to the second cover portion through the connecting portion and constituting a mounting surface relative to the portable information device, and an outer cover member extending from the first cover portion to the second cover portion through the connecting portion and constituting the outer surface of the cover member, wherein the heat conductive sheet may be held between the inner cover member and the outer cover member. With the above, the cover member can have a highly sophisticated design and a very pleasant touch feeling when the inner cover member and the outer cover member, to be touched by a hand of a user, are made of cloths, artificial leathers, or the like, while implementing high heat discharge capability attributed to the heat conductive sheet.

The heat conductive sheet may include a pair of protective layers and a graphite sheet held between the pair of protective layers. With the above, it is possible to implement high heat conductive capability attributed to the graphite sheet and prevention of, for example, crumbling of the graphite sheet attributed to the protective layers.

The protective layer may include a first protective member mounted on the first cover portion, a second protective member mounted on the second cover portion, and an intermediate protective member mounted on the connecting portion and connecting the first protective member and the second protective member, and the intermediate protective member may be made of material more flexible than the materials of the first protective member and the second protective member. With the above, the flexible intermediate protective member can smoothly follow the bending motion of the connecting portion. This makes it possible to prevent the intermediate protective member from being damaged due to its repetitive bending motions, and also to prevent the heat conductive sheet from becoming a load for the bending motion of the cover member.

The intermediate protective member may be made of polyimide.

The inner cover member may have an opening through which the heat conductive sheet is exposed. With the above, the cover member can absorb the heat from the portable information device directly with the heat conductive sheet. This can further improve the cooling capability.

The opening may be formed so as to overlap a part where at least one of heat generating elements of the portable information device is positioned when the cover member is mounted on the portable information device. With the above, the heat from the heat generating element is efficiently transmitted through the opening to the heat conductive sheet.

A covered portable information device according to the second aspect of the present invention is a covered portable information device including the portable information device having a cover member having the above described structure mounted thereon, wherein the portable information device includes a first chassis, a second chassis being adjacent to the first chassis and having a smaller heat generation amount than a heat generation amount of the first chassis, and a hinge connecting the first chassis and the second chassis in a foldable manner, the inner surface of the first cover portion of the cover member is mounted on the back surface of the first chassis, and the inner surface of the second cover portion of the cover member is mounted on the back surface of the second chassis.

A covered portable information device according to the third aspect of the present invention is a covered portable information device including the portable information device having a cover member having the above described structure mounted thereon, wherein the portable information device includes a chassis and a display mounted on the front surface of the chassis, the inner surface of the first cover portion of the cover member is mounted on the back surface of the chassis, and the second cover portion of the cover member is disposed so as to project to the side of the chassis and so as to cover and uncover the display.

With the above-described structure, the covered portable information device has an improved design and a more pleasant touch feeling attributed to the cover member. Moreover, the covered portable information device can avoid deterioration in performance due to the high temperature inside the chassis through heat dispersion by the cover member.

The above-described aspects of present invention can provide a cover member capable of dispersion of heat generated in a portable information device and a covered portable information device including the cover member and a portable information device.

### BRIEF DESCRIPTION OF THE DRAWINGS

FIG. 1 is a perspective view of a covered portable information device including a portable information device having a cover member according to one embodiment mounted thereon in a use state;

FIG. 2 is a side view of the covered portable information device illustrated in FIG. 1 in a stored state;

FIG. 3 is a schematic plan view of the inside structure of the covered portable information device illustrated in FIG. 1;

FIG. 4A is a schematic cross sectional view of the cover member in a use state;

FIG. 4B is a schematic cross sectional view of the cover member illustrated in FIG. 4A in a stored state;

FIG. 5 is a schematic cross sectional view of a cover member according to a modified example;

FIG. 6A is a side view of a covered portable information device including a portable information device according to a modified example, the portable information device having a cover member mounted thereon, in a use state; and

FIG. 6B is a side view of the covered portable information device illustrated in FIG. 6A, in a stored state.

### DETAILED DESCRIPTION OF THE INVENTION

A cover member and a covered portable information device according to the present invention will be described below in detail by way of preferable embodiments, referring to accompanying drawings.

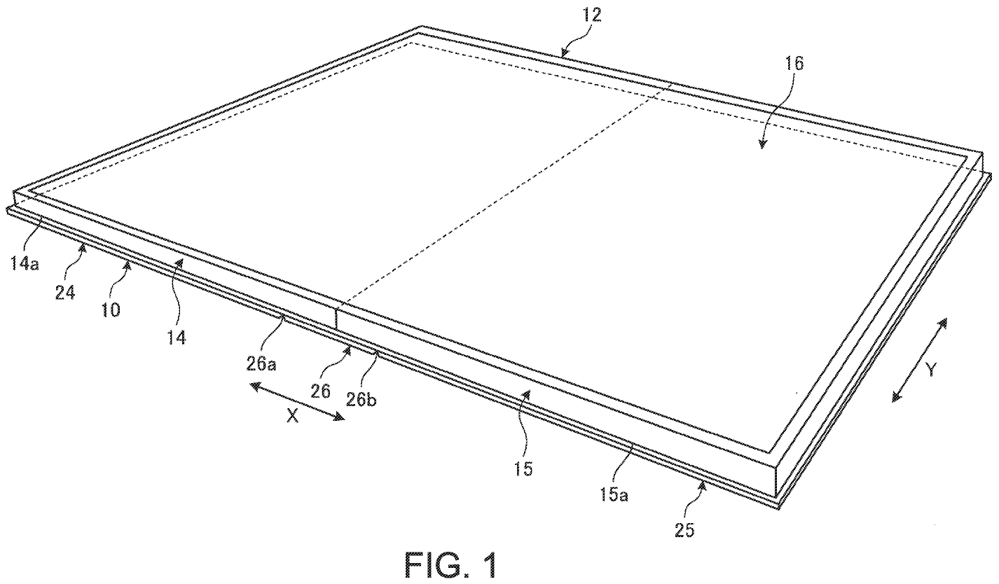

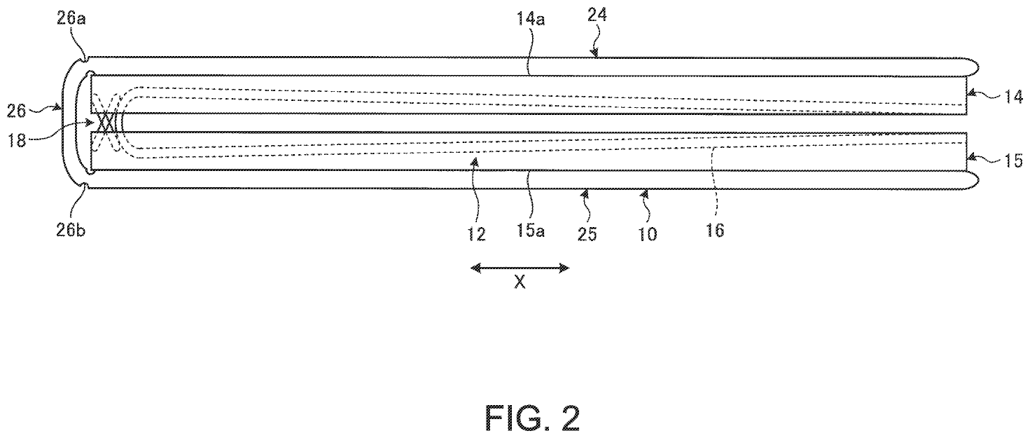

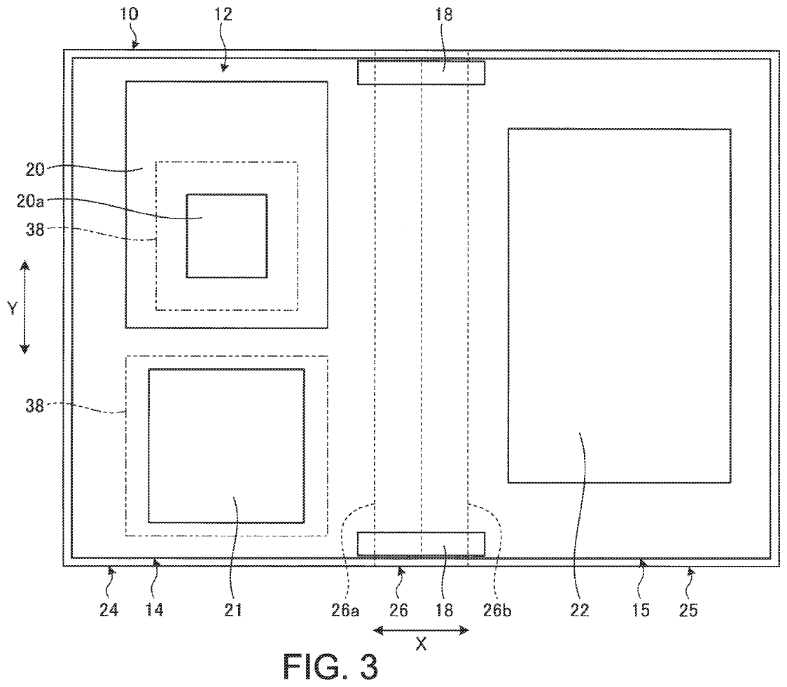

FIG. 1 is a perspective view of a covered portable information device including a portable information device 12 having a cover member 10 according to an embodiment mounted thereon in a use state. FIG. 2 is a side view of the covered portable information device illustrated in FIG. 1 in a stored state. FIG. 3 is a schematic plan view of the inside structure of the covered portable information device illustrated in FIG. 1.

As illustrated in FIG. 1 and FIG. 2, the cover member 10 has a protective function and a decorative function. The protective function is a function of protecting the portable information device 12 by covering the outer surface of the portable information device 12, and the decorative function is a function of improving the appearance design by decorating the outer surface of the portable information device 12. As an example of the portable information device 12, or an object on which the cover member 10 is to be mounted, a foldable tablet PC is referred to in this embodiment. Alternatively, the portable information device may be, for example, a single-panel tablet PC or a smartphone.

The portable information device 12 includes a pair of chassis 14, 15 and a display 16. The display 16 is omitted in FIG. 3.

The chassis 14, 15 are disposed adjacent to each other with their respective one edges abutting on and connected to each other via a hinge 18 in a foldable manner. One chassis 14 accommodates a substrate 20 carrying a central processing unit (CPU) 20a and electronic components such as a power source circuit 21. The other chassis 15 accommodates a battery device 22 and other electronic components. The CPU 20a is the largest heat generating element among the electronic components mounted in the portable information device 12, and the power source circuit 21 is the second largest heat generating element after the CPU 20a. Meanwhile, the battery device 22 generates a smaller amount of heat than those of the CPU 20a and the power source circuit 21. Consequently, different amounts of heat are generated between the right and left chassis 14, 15 of the portable information device 12, so that the temperature of the chassis 14 becomes higher than that of the chassis 15.

The display 16 is, for example, a touch panel liquid crystal display. The display 16 has a structure that can be folded together with the chassis 14, 15 being folded. That is, the display 16 is opened and closed along with the opening and closing motions of the chassis 14, 15. The display 16 is, for example, an organic electroluminescent (EL) flexible display having a highly flexible paper structure.

The cover member 10 and the portable information device 12 will now be described, based on an assumption that the direction in which the chassis 14, 15 are aligned is an X direction, and the direction along the adjacent edges of the chassis 14, 15 connected to each other via the hinge 18 is a Y direction.

As illustrated in FIG. 1 to FIG. 3, the cover member 10 changes its posture between being in a use state (refer to FIG. 1) in which the cover member 10 remains open in a panel-like state and being in a stored state (refer to FIG. 2) in which the cover member 10 is folded with the portable information device 12 stored inside, following the opening and closing motions of the portable information device 12. The cover member 10 includes a first cover portion 24, a second cover portion 25, and a connecting portion 26.

The first cover portion 24 is a portion that covers the back surface 14a of one chassis 14. The first cover portion 24 has an outer shape that can cover the substantially entire back surface 14a. Meanwhile, the second cover portion 25 is a portion that covers the back surface 15a of the other chassis 15. The second cover portion 25 has an outer shape that can cover the substantially entire back surface 15a.

The connecting portion 26 connects the first cover portion 24 and the second cover portion 25 in a foldable manner. One edge portion of the connecting portion 26 in the X direction is connected to the first cover portion 24 via a first folding line 26a in a bendable manner, and the other edge portion in the X direction is connected to the second cover portion 25 via a second folding line 26b in a bendable manner. The folding lines 26a, 26b extend in the Y direction. With the above, the connecting portion 26 functions as a flexible hinge that bendably connects the first cover portion 24 and the second cover portion 25.

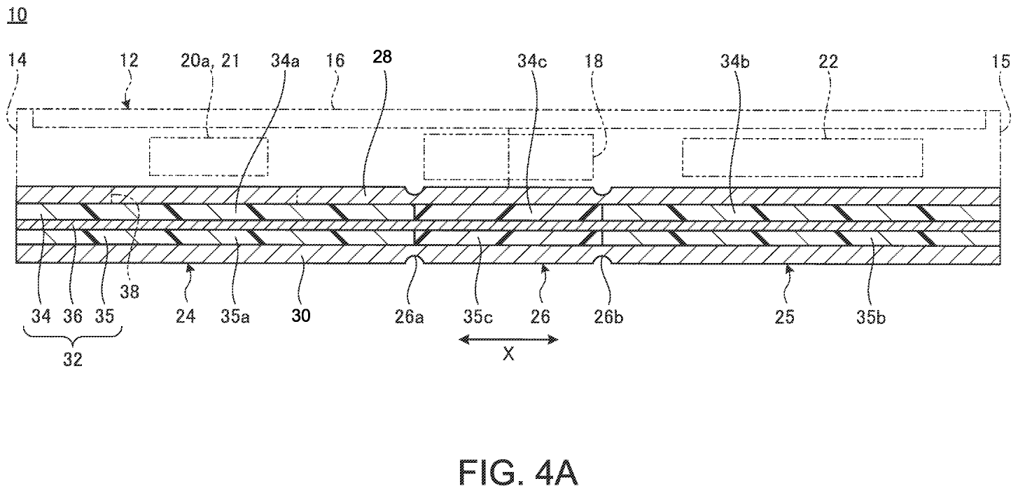

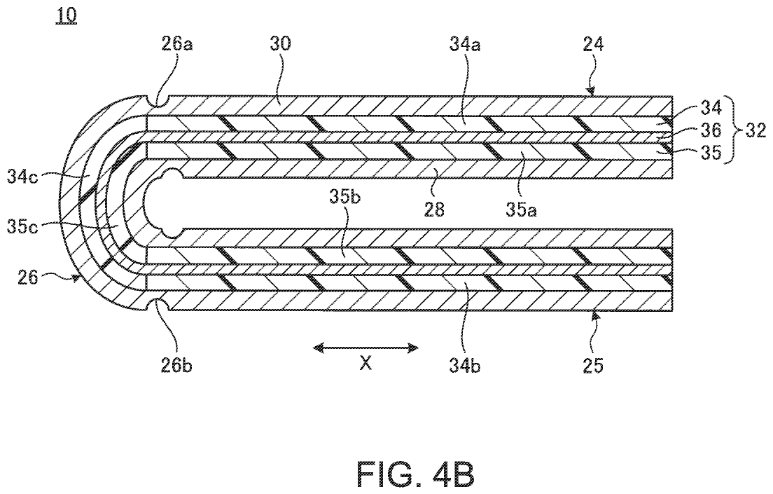

FIG. 4A is a schematic cross sectional view of the cover member 10 in a use state. FIG. 4B is a schematic cross sectional view of the cover member 10 illustrated in FIG. 4A in a stored state. As illustrated in FIG. 4A and FIG. 4B, the cover member 10 has a laminated structure including an inner cover member 28, an outer cover member 30, and a heat conductive sheet 32.

The inner cover member 28 is disposed so as to extend from the first cover portion 24 to the second cover portion 25 through the connecting portion 26. The inner cover member 28 constitutes the inner surface of the cover member 10. The inner cover member 28 also constitutes a mounting surface relative to the back surfaces 14a, 15a of the portable information device 12. The inner cover member is made of, for example, cloths, nonwoven fabrics, leathers, artificial leathers, rubbers, or silicone rubbers.

The outer cover member 30 is disposed so as to extend from the first cover portion 24 to the second cover portion 25 through the connecting portion 26. The outer cover member 30 constitutes the outer surface of the cover member 10. The outer cover member 30 is made of, for example, cloths, nonwoven fabrics, leathers, artificial leathers, rubbers, or silicone rubbers.

The heat conductive sheet 32 is disposed so as to extend from the first cover portion 24 to the second cover portion 25 through the connecting portion 26. The heat conductive sheet 32 is held between the inner cover member 28 and the outer cover member 30. The heat conductive sheet 32 is adhered to the respective cover members 28, 30 with adhesive agent or double stick tape, for example. The heat conductive sheet 32 has a three-layered structure including a pair of protective layers 34, 35 and a graphite sheet 36 held between the protective layers 34, 35.

The protective layer 34 on the inside includes a first protective member 34a, a second protective member 34b, and an intermediate protective member 34c.

The first protective member 34a is disposed in a position corresponding to the first cover portion 24. The second protective member 34b is disposed in a position corresponding to the second cover portion 25. Each of the first protective member 34a and the second protective member 34b is made, for example, using a graphite sheet 36 whose surface is coated with resin, for example, polyethylene terephthalate (PET).

The intermediate protective member 34c is disposed in a position corresponding to the connecting portion 26, and connects the first protective member 34a and the second protective member 34b. The intermediate protective member 34c is made of material more flexible or stretchable than those of the first protective member 34a and the second protective member 34b. The intermediate protective member 34c is made, for example, using a graphite sheet 36 whose surface is coated with polyimide (PI). Polyimide, which has superior stretching characteristic, is preferably usable for the connecting portion 26 subjected to repetitive bending motions.

The protective layer 35 on the outside includes a first protective member 35a, a second protective member 35b, and an intermediate protective member 35c. These protective members 35a to 35c may be made of the same materials as those of the respective protective members 34a to 34c of the protective layer 34 mentioned above. That is, while the first protective member 35a and the second protective member 35b are made of, for example, polyethylene terephthalate, the intermediate protective member 35c is made of, for example, polyimide. Note that the first protective member 35a and the second protective member 35b are omissible. In the case of omission, an adhesive layer including adhesive agent or double stick tape can be disposed at a part where the first protective member 35a and the second protective member 35b are disposed in FIG. 3A to adhere the graphite sheet 36 and the outer cover member 30.

The graphite sheet 36 is disposed so as to extend from the first cover portion 24 to the second cover portion 25 through the connecting portion 26. The graphite sheet 36 is a thin sheet made of graphite. The graphite sheet 36 has a very high thermal conductive rate. The surface of the graphite sheet 36 is covered with the protective layers 34, 35, whereby, for example, crumbling is prevented. The graphite sheet 36, which is light in weight and has a high thermal conductive rate, can efficiently disperse the heat received from the portable information device 12.

The heat conductive sheet 32 may include, for example, metal foil of copper or aluminum, instead of the graphite sheet 36. In the case that metal foil is used, the heat conductive sheet 32 may not include the protective layers 34, 35. Alternatively, the entirety or a part of the protective layers 34, 35, the part including the intermediate protective members 34c, 35c may be made of silicone rubber, for example.

As described above, the cover member 10 according to this embodiment includes the first cover portion 24, the second cover portion 25, the connecting portion 26 that connects the first cover portion 24 and the second cover portion 25 in a foldable manner, and a heat conductive sheet disposed so as to extend from the first cover portion 24 to the second cover portion 25 through the connecting portion 26.

Hence, the cover member 10 can absorb heat generated in the chassis 14 at higher temperature of the portable information device 12 with the heat conductive sheet 32, and efficiently disperse the heat, utilizing the heat conductive sheet 32 extending to the connecting portion 26 and the second cover portion 25. That is, the cover member 10 can absorb heat on the side with the chassis 14, with the first cover portion 24, and disperse the heat over a large area up to the second cover portion 25 on the side with the chassis 15 with smaller heat generation amount. The dispersion makes the temperature on the outer surface of the first cover portion 24 and the second cover portion 25 of the cover member 10 substantially constant. Consequently, the cover member 10 enables avoiding a situation in which a user feels uncomfortable due to the local high temperature in the first cover portion 24 positioned on the side with the chassis 14 at higher temperature.

Such a cover member 10 is integrally fixed to or removably mounted on the back surfaces 14a, 15b of the portable information device 12 with a screw, a magnet, or a hook, for example, not illustrated. Note here that as the portable information device 12 in this embodiment has a foldable structure, the cover member 10 mounted on the outer surface of the chassis 14, 15 will receive compressing or pulling force attributed to the difference in the turning radius when the chassis 14, 15 rotate around the hinge 18. In view of the above, it is preferable, for example, that the first cover portion 24 of the cover member 10 is stationarily fixed to the chassis 14 at higher temperature and that the second cover portion 25 is supported movably in the X direction relative to the chassis 15 at lower temperature. This makes it possible for the cover member 10 to reliably absorb the heat of the chassis 14 with the first cover portion 24 and also to smoothly cope with the difference in the turning radius when the chassis 14, 15 are being folded. This can prevent unintended dropout or removal of the cover member 10.

The heat conductive sheet 32 has a structure including the graphite sheet 36 and the protective layers 34, 35 on the surfaces of the graphite sheet 36. This structure can implement high heat conductive capability attributed to the graphite sheet 36 and also prevention of crumbling or the like of the graphite sheet 36, attributed to the protective layers 34, 35. In particular, since a portion of the heat conductive sheet 32 corresponding to the connecting portion 26 is subjected to repetitive bending motions and the graphite sheet 36 there is thus easily damaged, the protective layers 34, 35 are preferably disposed at least on a portion corresponding to the connecting portion 26. That is, the protective layers 34, 35 can have any structure including at least the intermediate protective members 34c, 35c.

The cover member 10 has a structure including the heat conductive sheet 32 held between the inner cover member 28 and the outer cover member 30. With this structure, the cover member 10 can have a highly sophisticated design and a very pleasant touch feeling when the inner cover member 28 and the outer cover member 30, to be touched by a hand of a user, are made of cloths, artificial leathers, or the like, while implementing high heat discharge capability attributed to the heat conductive sheet 32.

As indicated by the long dashed double-short dashed line in FIG. 3 and FIG. 4A, the inner cover member 28 may have an opening 38 at a position that overlaps at least one of the heat generating elements, such as the CPU 20a and the power source circuit 21. The opening 38 allows the heat generated by the CPU 20a or the like to be transmitted directly to the heat conductive sheet 32 via the chassis 14. This resultantly further improves the cooling efficiency by the heat conductive sheet 32 as the inner cover member 28 does not hinder heat transmission from the heat generating element to the heat conductive sheet 32. In the case that the portable information device 12 has, for example, a structure having a heat pipe or the like inside the chassis to transmit heat from the CPU 20a therethrough, the opening 38 is preferably formed at a position corresponding to the end portion of the heat pipe.

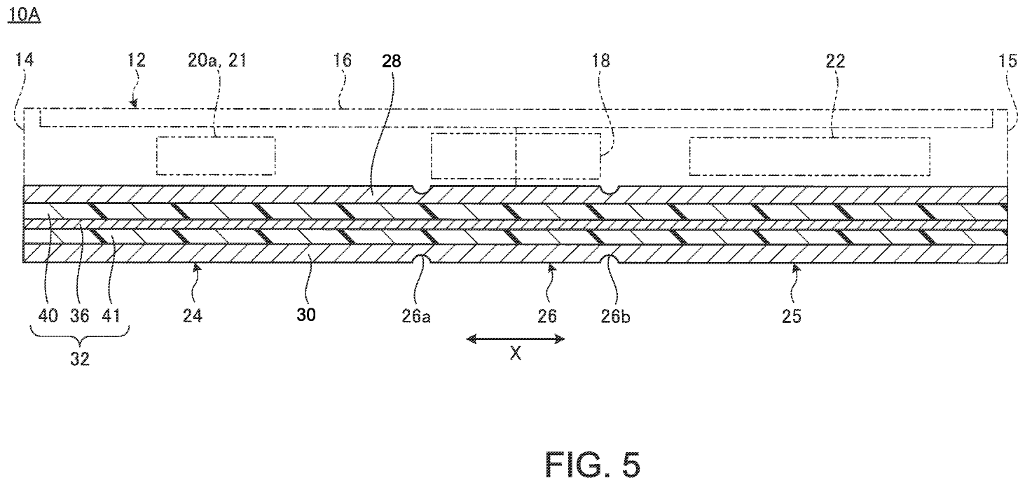

FIG. 5 is a schematic cross sectional view of a cover member 10A according to a modified example. The cover member 10A illustrated in FIG. 5 has a heat conductive sheet including a graphite sheet 36 whose surfaces are respectively covered with protective layers 40, 41 having different structures from those of the protective layers 34, 35, illustrated in FIG. 4A. Specifically, the protective layers 40, 41 have structures similar to those of the intermediate protective members 34c, 35c of the protective layers 34, 35, and are made of polyimide. Such a structure enables improved manufacturing efficiency of the heat conductive sheet 32, though polyimide is more expensive than resin material, such as polyethylene terephthalate. In view of the above, only the intermediate protective members 34c, 35c of the protective layers 34, 35, illustrated in FIG. 4A, are made of polyimide to reduce the cost of products. Note that, for specifications with less demand on the number of times of repetitive bending motions of the connecting portion 26, the entire protective layers 40, 41 may be made of polyethylene terephthalate instead of polyimide.

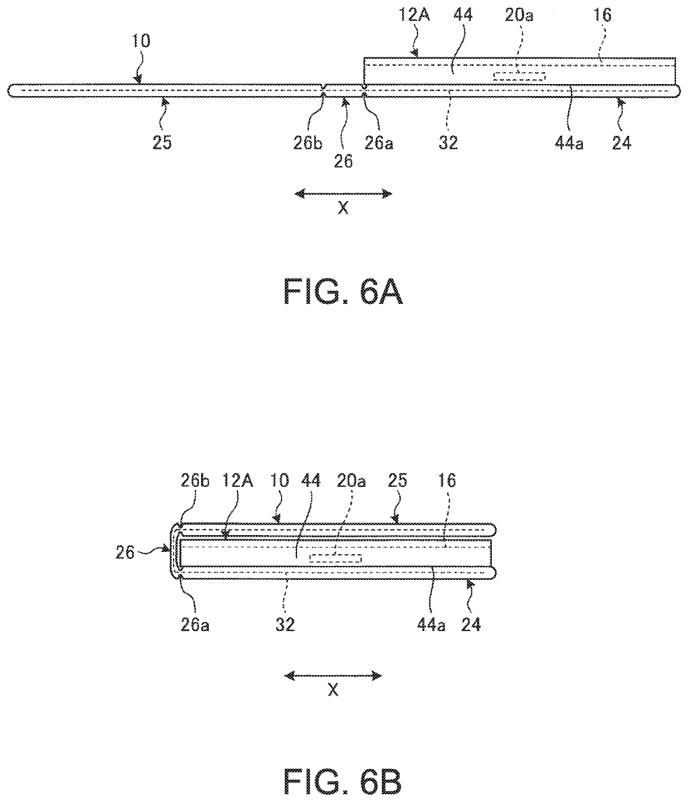

FIG. 6A is a side view of a covered portable information device including a portable information device 12A according to a modified example and the cover member 10 mounted on the portable information device 12A, in a use state. FIG. 6B is a side view of the covered portable information device illustrated in FIG. 6A in a stored state.

As illustrated in FIG. 6A and FIG. 6B, the portable information device 12A is a typical, that is, not foldable, tablet PC or smartphone. The cover member 10 is mounted such that the first cover portion 24 covers the back surface 44a of the chassis 44 of the portable information device 12A. In a use state illustrated in FIG. 6A, the second cover portion 25 and the connecting portion 26 project to the side of the chassis 44. When the second cover portion 25 is folded via the connecting portion 26 so as to cover the display 16, the cover member 10 is placed in a stored state, illustrated in FIG. 6B.

Thus, the cover member 10 can absorb heat from the heat generating element with the first cover portion 24 and disperse the heat utilizing the second cover portion 25 as well also when being mounted on such a portable information device 12A, so that the cover member 10 can implement high cooling capability.

The present invention should not be construed to be limited to the above-described embodiment. Needless to say, the present invention can be freely modified within a range without departing from the gist of the present invention.

In the above, a structure in which the heat conductive sheet 32 is mounted over the substantially entire area including the first cover portion 24, the connecting portion 26, and the second cover portion 25 has been described as an example. The heat conductive sheet 32, however, may have any structure that can absorb heat from a heat generating element with the first cover portion 24 and disperse the heat with the first cover portion 24 and the second cover portion 25. That is, the heat conductive sheet 32 is not necessarily mounted over the entire area of the cover member 10, and coverage of at least respective parts of the first cover portion 24, the connecting portion 26, and the second cover portion 25 by the heat conductive sheet 32 is sufficient. Nevertheless, it is desirable that the heat conductive sheet 32 of the first cover portion 24 is positioned immediately below a heat generating element.

In the above, tablet PCs and smartphones are referred to as examples of the portable information device 12, 12A. Alternatively, the portable information device may be a laptop PC, for example. In mounting the cover member 10 on a laptop PC, the first cover portion 24 can be mounted on the back surface of the main body chassis having a keyboard device and a CPU, and the second cover portion 25 can be mounted on the back surface of the display chassis having a display.

In the above, a structure in which the entire heat conductive sheet 32, namely, from the first cover portion 24 to the second cover portion 25 through the connecting portion 26, is made using a single sheet has been described as an example. Alternatively, the heat conductive sheet 32 may has a structure including a plurality of sheets connected to each other in a thermally transmissible manner.

1. A cover member for mounting on a portable information device, comprising:
a first cover portion;
a second cover portion;
a connecting portion connecting, in a foldable manner, the first cover portion and the second cover portion; and
a heat conductive sheet that extends from the first cover portion to the second cover portion, and through the connecting portion.

2. The cover member according to claim 1, further comprising:
an inner cover member that extends from the first cover portion to the second cover portion, and through the connecting portion, and constituting a mounting surface relative to the portable information device, and
an outer cover member that extends from the first cover portion to the second cover portion, and through the connecting portion, and constituting an outer surface of the cover member,
wherein the heat conductive sheet is held between the inner cover member and the outer cover member.

3. The cover member according to claim 2, wherein the heat conductive sheet includes a pair of protective layers and a graphite sheet held between the pair of protective layers.

4. The cover member according to claim 3, wherein:
the protective layer includes:
a first protective member mounted on the first cover portion,
a second protective member mounted on the second cover portion, and
an intermediate protective member mounted on the connecting portion, and connecting the first protective member with the second protective member, and
the intermediate protective member is made of material more flexible than materials of the first protective member and the second protective member.

5. The cover member according to claim 4, wherein the intermediate protective member is made of polyimide.

6. The cover member according to claim 2, wherein the inner cover member has an opening through which the heat conductive sheet is exposed.

7. The cover member according to claim 6, wherein the opening is configured to overlap a part where at least one of heat generating elements of the portable information device is positioned when the cover member is mounted on the portable information device.

8. A covered portable information device including a cover member mounted on a portable information device, wherein:
the cover member includes:
a first cover portion;
a second cover portion;
a connecting portion connecting, in a foldable manner, the first cover portion and the second cover portion; and
a heat conductive sheet that extends from the first cover portion to the second cover portion, and through the connecting portion; the portable information device includes:
a first chassis,
a second chassis adjacent to the first chassis and having a smaller heat generation amount than a heat generation amount of the first chassis, and
a hinge connecting, in a foldable manner, the first chassis and the second chassis,
an inner surface of the first cover portion of the cover member is mounted on a back surface of the first chassis, and
an inner surface of the second cover portion of the cover member is mounted on a back surface of the second chassis.

9. A covered portable information device including a cover member mounted on a portable information device, wherein:
the cover member includes:
a first cover portion;
a second cover portion;
a connecting portion connecting, in a foldable manner, the first cover portion and the second cover portion; and
a heat conductive sheet that extends from the first cover portion to the second cover portion, and through the connecting portion; the portable information device includes:
a chassis, and
a display mounted on a front surface of the chassis,
an inner surface of the first cover portion of the cover member is mounted on a back surface of the chassis, and
the second cover portion of the cover member projects to a side of the chassis and to cover and uncover the display.
